(19) United States
(12) Patent Application Publication
(10) Pub. No.: US 2026/0101603 A1
(43) Pub. Date: Apr. 9, 2026

(54) IMAGE SENSOR CHIP AND SEMICONDUCTOR PACKAGE INCLUDING THE SAME

(71) Applicant: Samsung Electronics Co., Ltd., Suwon-si (KR)

(72) Inventor: Sang-Uk Kim, Suwon-si (KR)

(21) Appl. No.: 19/275,119

(22) Filed: Jul. 21, 2025

(30) Foreign Application Priority Data
Oct. 8, 2024 (KR) 10-2024-0136808

(51) Int. Cl. H10F 39/95; H10F 39/00

(52) U.S. Cl. CPC H10F 39/95; H10F 39/804; H10F 39/811

(57) ABSTRACT

A semiconductor package may include a package substrate, a first image sensor chip and a second image sensor chip, which are on the package substrate and are spaced apart from each other in a first direction, and a bonding wire connecting the first image sensor chip to the second image sensor chip. The first image sensor chip may include a first conductive pad, and the second image sensor chip may include a second conductive pad. The bonding wire may be connected to the first conductive pad and the second conductive pad.

### CROSS-REFERENCE TO RELATED APPLICATIONS

This U.S. non-provisional patent application claims priority under 35 U.S.C. § 119 to Korean Patent Application No. 10-2024-0136808, filed on Oct. 8, 2024, in the Korean Intellectual Property Office, the entire contents of which are hereby incorporated by reference.

### BACKGROUND OF THE INVENTION

The present disclosure relates to a semiconductor package, and in particular, to a semiconductor package including an image sensor chip.

An image sensor, such as a charge-coupled device (CCD) sensor or a complementary metal-oxide-semiconductor (CMOS) image sensor, is applied to various electronic products, such as mobile phones, digital cameras, optical mice, security cameras, and biometric devices. Due to an increasing demand for small and multifunctional electronic products, a semiconductor package including an image sensor should be prepared to have improved technical properties (e.g., small size, high density, low power consumption, multifunction, high signal-processing speed, high reliability, low cost, and clear image quality). Various researches are being conducted to realize such technical properties of the semiconductor package.

### SUMMARY

Some embodiments of the inventive concept include a semiconductor package, in which image sensor chips with different characteristics are provided, and which have various properties.

According to some embodiments of the inventive concept, a semiconductor package may include a package substrate, a first image sensor chip and a second image sensor chip on the package substrate and spaced apart from each other in a first direction, and a bonding wire connecting the first image sensor chip to the second image sensor chip. The first image sensor chip may include a first conductive pad, the second image sensor chip may include a second conductive pad, and the bonding wire may be connected to the first and second conductive pads.

According to an embodiment of the inventive concept, a semiconductor package may include a package substrate, and a first image sensor chip and a second image sensor chip on the package substrate and spaced apart from each other in a first direction. The package substrate may have a first length in a first direction parallel to a top surface of the package substrate. The first image sensor chip may have a first side surface and a second side surface, which are opposite to each other in the first direction. The second image sensor chip may have a third side surface and a fourth side surface, which are opposite to each other in the first direction. The first side surface may be closer to an edge of the package substrate than the second side surface, and the fourth side surface may be closer to an edge of the package substrate than the third side surface. A distance between the first and fourth side surfaces in the first direction may have a second length, and the second length may be 70 % to 80 % of the first length.

According to an embodiment of the inventive concept, a semiconductor package may include a package substrate, a first image sensor chip and a second image sensor chip on the package substrate and spaced apart from each other in a first direction parallel to a top surface of the package substrate, a first bonding wire connecting the package substrate to the first image sensor chip, a second bonding wire connecting the package substrate to the second image sensor chip, a third bonding wire connecting the first image sensor chip to the second image sensor chip, a transparent substrate on the first and second image sensor chips, and a mold layer between the package substrate and the transparent substrate.

### BRIEF DESCRIPTION OF THE DRAWINGS

FIG. 1 is a plan view illustrating a semiconductor package according to some embodiments of the inventive concept.

FIG. 2 is a sectional view taken along a line A-A′ of FIG. 1.

FIG. 3 is a plan view illustrating a semiconductor package according to some embodiments of the inventive concept.

FIG. 4 is a sectional view taken along a line B-B′ of FIG. 4.

FIG. 5 is a sectional view illustrating a semiconductor package according to some embodiments of the inventive concept.

FIGS. 6A, 6B, 6C, and 6D are diagrams illustrating arrays of color filters according to some embodiments of the inventive concept.

FIG. 7 is a sectional view illustrating an image sensor according to some embodiments of the inventive concept.

FIGS. 8, 9, and 10 are sectional views illustrating a process of fabricating an image sensor according to some embodiments of the inventive concept.

FIG. 11 is a sectional view illustrating a portion of a process of fabricating an image sensor according to some embodiments of the inventive concept.

### DETAILED DESCRIPTION

Example embodiments of the inventive concepts will now be described more fully with reference to the accompanying drawings, in which example embodiments are shown.

It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process. Thus, “first”, “second” and/or “third” may be used selectively or interchangeably in describing each material, layer, region, electrode, pad, pattern, structure or process.

The terms “comprises,” “comprising,” “includes” and/or “including,” when used herein, specify the presence of stated elements, but do not preclude the presence of additional elements. The term “and/or” includes any and all combinations of one or more of the associated listed items.

The term “connected” may be used herein to refer to a physical and/or electrical connection.

A first element described as “on” a second element may be disposed directly on the second element (e.g., in contact with the second element) or indirectly on the second element (e.g., with an intervening element interposed between the first and second elements). When components or layers are referred to herein as “directly” on, or “in direct contact” or “directly connected,” no intervening components or layers are present.

Further, spatially relative terms, such as “under,” “below,” “lower,” “over,” “upper”, etc., may be used herein for ease of description to describe one element or relationship of structures to another element or structure as illustrated in the drawings.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

The term “overlap” (or “overlapping,” or like terms), as may be used herein, is intended to broadly refer to a first element that intersects with at least a portion of a second element in the vertical direction, but does not require that the first and second elements be completely aligned with one another in a horizontal plane.

The term “exposed” may be used to describe relationships between elements and/or certain intermediate processes in fabricating a completed semiconductor device but may not necessarily require exposure of the particular region, layer, structure or other element in the context of the completed device. An “element A is exposed through an element B” means that at least a portion of the element A is not covered by the element B. However, the thus exposed portion of the element A may be covered by a third element.

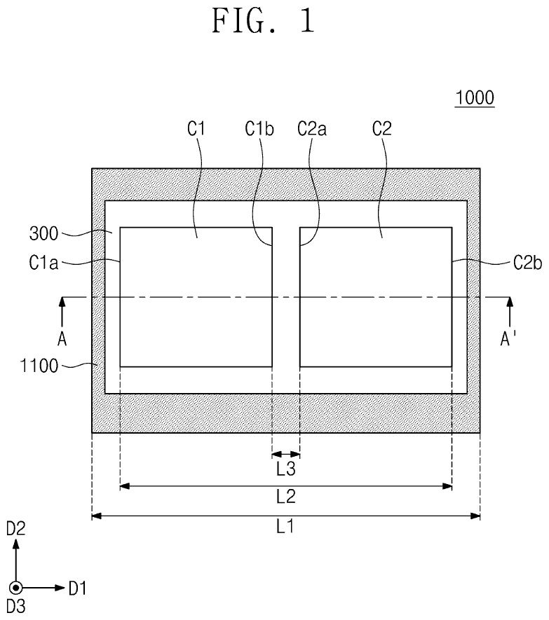

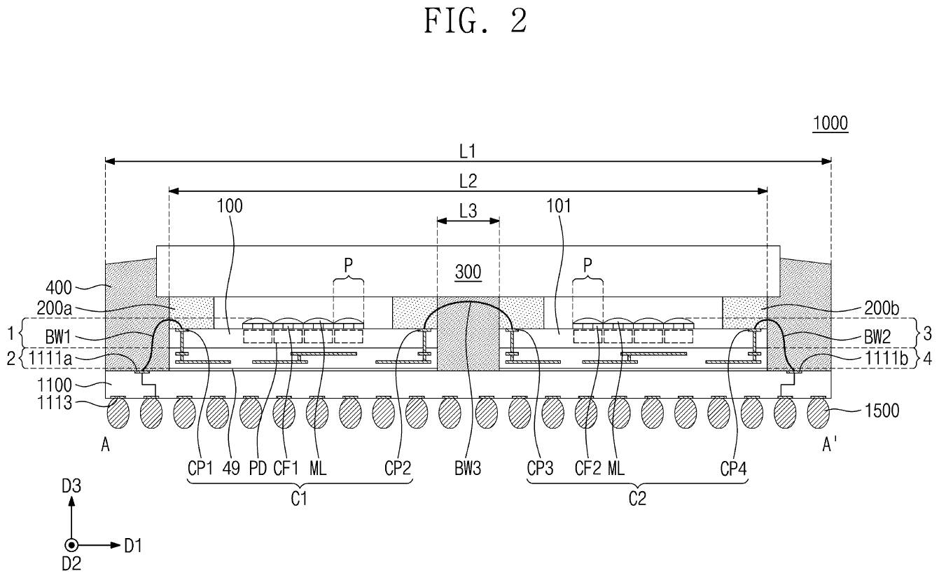

FIG. 1 is a plan view illustrating a semiconductor package according to some embodiments of the inventive concept. FIG. 2 is a sectional view taken along a line A-A′ of FIG. 1.

Referring to FIGS. 1 and 2, a semiconductor package 1000 may include a package substrate 1100, a first image sensor chip C1, a second image sensor chip C2, a transparent substrate 300, and a mold layer 400.

The package substrate 1100 may be, for example, a printed circuit board (PCB). The package substrate 1100 may have a first length L1 in a first direction D1.

In the present specification, the first direction D1 may be defined to be a direction parallel to a top surface of the package substrate 1100. A second direction D2 may be parallel to the top surface of the package substrate 1100 and may be perpendicular to the first direction D1. A third direction D3 may be perpendicular to the top surface of the package substrate 1100.

The package substrate 1100 may include bonding pads 1111a and 1111b on a top surface thereof, coupling pads 1113 on a bottom surface thereof, and internal interconnection lines. The bonding pads 1111a and 1111b may be electrically connected to the coupling pads 1113 through the internal interconnection lines. The bonding pads 1111a and 1111b may include first bonding pads 1111a and second bonding pads 1111b, which are spaced apart from each other in the first direction D1.

Outer connection terminals 1500 may be on the coupling pads 1113, respectively. The outer connection terminals 1500 may include solder balls or solder bumps. Depending on the kind and arrangement of the outer connection terminals 1500, the semiconductor package may be classified as a ball grid array (BGA), a fine ball-grid array (FBGA), or a land grid array (LGA). The outer connection terminal 1500 may be formed of or include at least one of tin (Sn), silver (Ag), copper (Cu), nickel (Ni), bismuth (Bi), indium (In), antimony (Sb), cerium (Ce), or alloys thereof.

The first image sensor chip C1 may be on the package substrate 1100. In detail, the first image sensor chip C1 may be mounted on the package substrate 1100 through a bonding tape 49 on a top surface of the package substrate 1100. Referring to FIG. 1, the first image sensor chip C1 may have a first side surface C1a and a second side surface C1b, which are opposite to each other. The first side surface C1a may be closer to an edge of the package substrate 1100 than the second side surface C1b.

The first image sensor chip C1 may include a first sensor unit 1 and a first logic unit 2. The first logic unit 2 may be closer to the package substrate 1100 than the first sensor unit 1.

The first sensor unit 1 may be configured to sense light, and the first logic unit 2 may include circuits that are configured to convert the light, which is sensed by the first sensor unit 1, to electrical signals and to drive the first sensor unit 1.

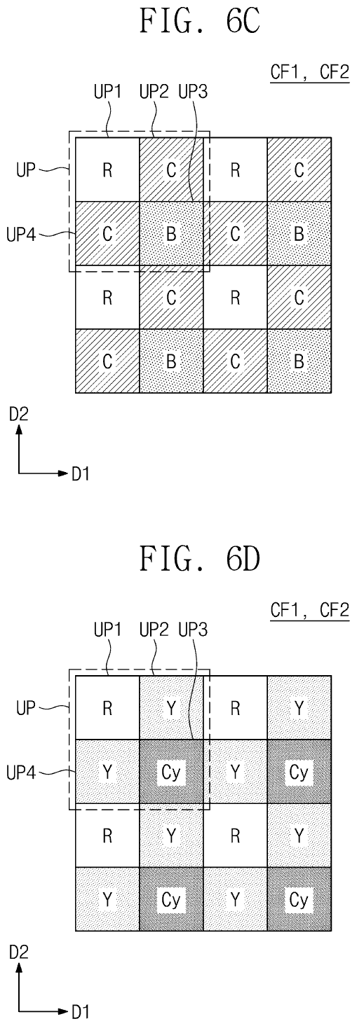

In some embodiments, the first logic unit 2 may include circuits that are configured to perform a global shutter operation, in which all pixels of the first image sensor chip C1 are simultaneously exposed to light. In some embodiments, the first logic unit 2 may include circuits that are configured to perform a rolling shutter operation, in which the pixels of the first image sensor chip C1 are sequentially exposed and read out. The first sensor and logic units 1 and 2 will be described in more detail with reference to FIG. 7.

The first sensor unit 1 may include a first semiconductor substrate 100, a first color filter CF1, and a micro lens ML. The first semiconductor substrate 100 may be a single crystalline wafer or an epitaxial layer, which is formed of silicon and/or germanium, or a silicon-on-insulator (SOI) wafer.

The first semiconductor substrate 100 may include a plurality of photoelectric conversion parts PD. The first semiconductor substrate 100 may be doped with a first impurity to have a first conductivity type. The first impurity may be, for example, boron. The first conductivity type may be, for example, a p-type.

The photoelectric conversion parts PD may be doped with a second impurity to have a second conductivity type different from the first conductivity type. The second impurity may be, for example, phosphorus or arsenic. The second conductivity type may be, for example, an n-type. The first semiconductor substrate 100 of the first conductivity type and the photoelectric conversion part PD of the second conductivity type may form a junction serving as photodiodes. The photoelectric conversion part PD may be configured to generate photocharges in proportional to the intensity of the incident light.

A first conductive pad CP1 and a second conductive pad CP2 may be on a top surface of the first semiconductor substrate 100. The first conductive pad CP1 may be in a region adjacent to the first side surface C1a of the first image sensor chip C1. The second conductive pad CP2 may be in a region adjacent to the second side surface C1b of the first image sensor chip C1.

The first color filters CF1 may be on the first semiconductor substrate 100. The first color filters CF1 may be correspond to the photoelectric conversion parts PD in the first semiconductor substrate 100.

The micro lenses ML may be on the first color filters CF1. The first color filter CF1, the micro lens ML corresponding to the first color filter CF1, and one or more photoelectric conversion part PD corresponding to the first color filter CF1 and the micro lens ML may be defined as a unit pixel P. A plurality of unit pixels P may be two-dimensionally arranged on the top surface of the first semiconductor substrate 100.

A first dam structure 200a may be between the first image sensor chip C1 and the transparent substrate 300. The first dam structure 200a may be on an edge portion of the first image sensor chip C1 to cover the first conductive pad CP1 and the second conductive pad CP2. The first dam structure 200a may have a closed-loop shape.

The first dam structure 200a may be used to fasten the transparent substrate 300 and to separate the first image sensor chip C1 from the transparent substrate 300. That is, an empty space between the transparent substrate 300 and the first image sensor chip C1 may be provided by the first dam structure 200a. The first dam structure 200a may be provided to hermetically seal an empty space between the transparent substrate 300 and the first image sensor chip C1 and to prevent moisture or a contamination material from the outside from entering the empty space.

The first dam structure 200a may include an insulating material. For example, the first dam structure 200a may be formed of or include at least one of epoxy resins, polyimide, or resist materials. The first dam structure 200a may include a dry film resist (DFR) or an insulating material.

The second image sensor chip C2 may be on the package substrate 1100 and may be spaced apart from the first image sensor chip C1 in the first direction D1. In detail, the second image sensor chip C2 may be mounted on the package substrate 1100 through the bonding tape 49 on the top surface of the package substrate 1100. The second image sensor chip C2 may be a chip different from the first image sensor chip C1. In some embodiments, the second image sensor chip C2 may be the same chip as the first image sensor chip C1.

Referring to FIG. 1, the second image sensor chip C2 may have a third side surface C2a and a fourth side surface C2b, which are opposite to each other. The fourth side surface C2b may be closer to an edge of the package substrate 1100 than the third side surface C2a. Here, a distance between the first side surface C1a of the first image sensor chip C1 and the fourth side surface C2b of the second image sensor chip C2 in the first direction D1 may have a second length L2. The second length L2 may range from 70 % to 80 % of the first length L1. Since the length of a region of the package substrate 1100, on which the first and second image sensor chips C1 and C2 are positioned, is 70 % to 80% of a width of the package substrate 1100, a process yield of the fabrication process may be increased.

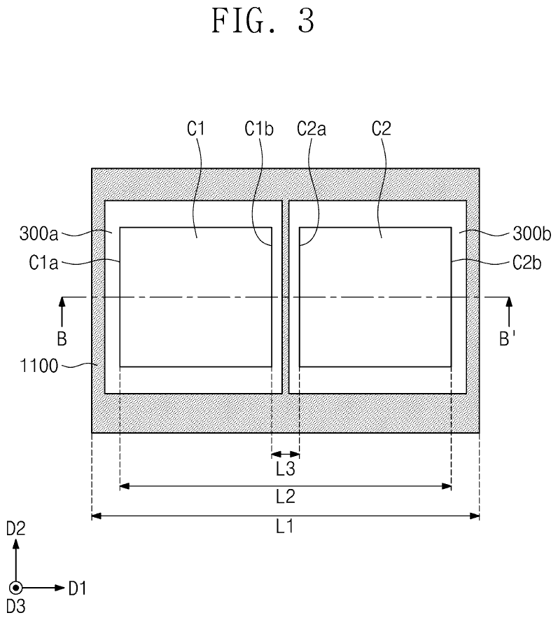

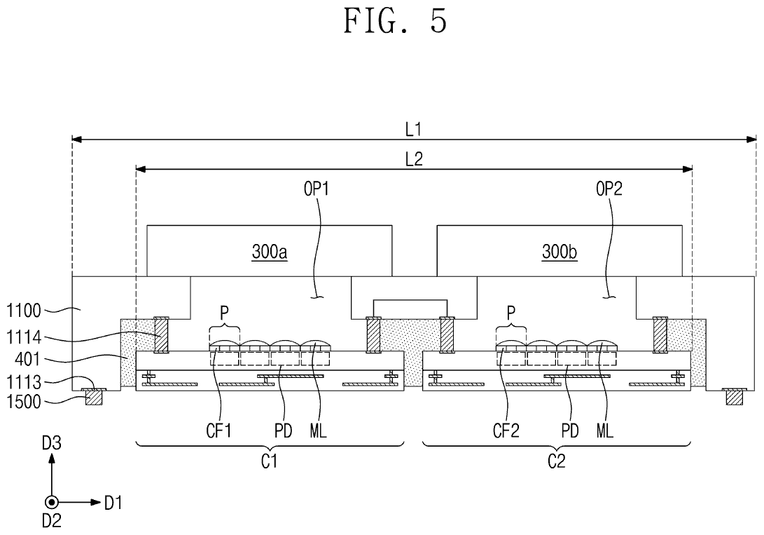

A distance between the second side surface C1b of the first image sensor chip C1 and the third side surface C2a of the second image sensor chip C2 in the first direction D1 may have a third length L3. The third length L3 may correspond to a minimum distance between the first and second image sensor chips C1 and C2 in the first direction D1. The third length L3 may be, for example, about 60 μm. The first to third lengths L1 to L3 may be configured to have substantially the same features as those of FIGS. 3 and 5.

The second image sensor chip C2 may include a second sensor unit 3 and a second logic unit 4. The second logic unit 4 may be closer to the package substrate 1100 than the second sensor unit 3. The second sensor unit 3 may be configured to sense light, and the second logic unit 4 may include circuits that are configured to convert light sensed by the second sensor unit 3 to electrical signals and are used to drive the second sensor unit 3. As an example, the second logic unit 4 may include circuits that are configured to perform a global shutter operation, in which all pixels of the second image sensor chip C2 are simultaneously exposed to light. As another example, the second logic unit 4 may include circuits that are configured to perform a rolling shutter operation, in which the pixels of the second image sensor chip C2 are sequentially exposed and read out. In some embodiments, the second logic unit 4 may include circuits that are configured to perform a different shutter operation from the first logic unit 2. In this case, since a plurality of image sensor chips C1 and C2 mounted are configured to perform different shutter operations, the shutter operation may be performed in an optimized manner for various situations. In the global shutter operation, it may be possible to obtain a clear image of a moving subject or minimize a distortion phenomenon, such as the jello-effect. The rolling shutter operation may be cost-effective and may have improved thermal characteristics, compared with the global shutter operation, and due to the two image sensor chips C1 and C2 within a single package, one of the two shutter operations may be adaptively performed, depending on the desired purpose.

The second sensor unit 3 may include a second semiconductor substrate 101, a second color filter CF2, and the micro lens ML. The second semiconductor substrate 101 may be a single crystalline wafer or an epitaxial layer, which is formed of silicon and/or germanium, or a silicon-on-insulator (SOI) wafer.

The second semiconductor substrate 101 may include a plurality of photoelectric conversion parts PD. The second semiconductor substrate 101 may be doped with a first impurity to have a first conductivity type. The first impurity may be, for example, boron. The first conductivity type may be, for example, a p-type.

The photoelectric conversion parts PD may be doped with a second impurity to have a second conductivity type different from the first conductivity type. The second impurity may be, for example, phosphorus or arsenic. The second conductivity type may be, for example, an n-type. The second semiconductor substrate 101 of the first conductivity type and the photoelectric conversion part PD of the second conductivity type may form a junction serving as photodiodes. The photoelectric conversion part PD may be configured to generate photocharges in proportional to the intensity of the incident light.

Here, the number of the photoelectric conversion parts PD per unit area in the second semiconductor substrate 101, may differ from the number of the photoelectric conversion parts PD per unit area in the first semiconductor substrate 100. In some embodiments, the number of the photoelectric conversion parts PD per unit area in the first semiconductor substrate 100 may be larger than the number of the photoelectric conversion parts PD per unit area in the second semiconductor substrate 101. The numbers of the photoelectric conversion parts PD per unit area in the first and second semiconductor substrates 100 and 101 may be different from each other, and the first and second image sensor chips C1 and C2 may have different resolutions from each other. As a result, image sensors, which can be used in various situations (e.g., capturing images over a large area or performing precise analysis), may be provided within a single semiconductor package, thereby enhancing price competitiveness.

A third conductive pad CP3 and a fourth conductive pad CP4 may be on a top surface of the second semiconductor substrate 101. The third conductive pad CP3 may be in a region adjacent to the third side surface C2a of the second image sensor chip C2. The fourth conductive pad CP4 may be in a region adjacent to the fourth side surface C2b of the second image sensor chip C2.

The second color filters CF2 may be on the second semiconductor substrate 101. The second color filters CF2 may be correspond to the photoelectric conversion parts PD in the second semiconductor substrate 101.

The micro lenses ML may be on the second color filters CF2. The second color filter CF2, the micro lens ML corresponding to the second color filter CF2, and one or more photoelectric conversion parts PD corresponding to the second color filter CF2 and the micro lens ML may be defined as the unit pixel P. The unit pixels P may be two-dimensionally arranged on the top surface of the second semiconductor substrate 101.

A second dam structure 200b may be between the second image sensor chip C2 and the transparent substrate 300. The second dam structure 200b may be on an edge portion of the second image sensor chip C2 to cover the third and fourth conductive pads CP3 and CP4. The second dam structure 200b may have a closed-loop shape.

The second dam structure 200b may be used to fasten the transparent substrate 300 and to separate the second image sensor chip C2 from the transparent substrate 300. That is, an empty space may be provided between the transparent substrate 300 and the second image sensor chip C2 by the second dam structure 200b. The second dam structure 200b may be provided to hermetically seal an empty space between the transparent substrate 300 and the second image sensor chip C2 and to prevent moisture of a contamination material from the outside from entering the empty space.

The second dam structure 200b may include an insulating material. For example, the second dam structure 200b may include at least one of epoxy resins, polyimide, or resist materials. The second dam structure 200b may include a dry film resist (DFR) or an insulating material.

A first bonding wire BW1 may connect the package substrate 1100 to the first image sensor chip C1. In detail, the first bonding wire BW1 may connect the first bonding pad 1111a of the package substrate 1100 to the first conductive pad CP1 of the first image sensor chip C1. The package substrate 1100 and the first image sensor chip C1 may be electrically connected to each other through the first bonding wire BW1. The first bonding wire BW1 may include a metallic material.

A second bonding wire BW2 may connect the package substrate 1100 to the second image sensor chip C2. In detail, the second bonding wire BW2 may connect the second bonding pad 1111b of the package substrate 1100 to the fourth conductive pad CP4 of the second image sensor chip C2. The package substrate 1100 and the second image sensor chip C2 may be electrically connected to each other through the second bonding wire BW2. The second bonding wire BW2 may include a metallic material.

A third bonding wire BW3 may connect the first image sensor chip C1 to the second image sensor chip C2. In detail, the third bonding wire BW3 may connect the second conductive pad CP2 of the first image sensor chip C1 to the third conductive pad CP3 of the second image sensor chip C2. The first and second image sensor chips C1 and C2 may be electrically connected to each other through the third bonding wire BW3. The third bonding wire BW3 may include a metallic material.

The first and second image sensor chips C1 and C2 may exchange signals (e.g., pixel data signals or control signals) through the third bonding wire BW3. Since the signals are directly transmitted between two image sensor chips C1 and C2 through the third bonding wire BW3, the signal transmission speed may be increased. In some embodiments, the interconnection between the first and second image sensor chips C1 and C2 may be provided meet a specific protocol (e.g., MIPI).

In addition, since the third bonding wire BW3 is provided outside the package substrate 1100 and are spaced apart from the internal interconnection lines in the package substrate 1100, a cross-talk issue between the first and second image sensor chips C1 and C2 may be reduced. Furthermore, since the first and second image sensor chips C1 and C2 are directly connected to each other through the third bonding wire BW3, a distance between the first and second image sensor chips C1 and C2 on the package substrate 1100 may be reduced. As a result, it may be possible to improve the yield and the integration density in the process of fabricating the semiconductor package.

The transparent substrate 300 may be spaced apart from the first and second image sensor chips C1 and C2 by the first and second dam structures 200a and 200b. The transparent substrate 300 may be in contact with the first and second dam structures 200a and 200b. When viewed in a plan view, the transparent substrate 300 may be overlapped with the first and second image sensor chips C1 and C2. A width of the transparent substrate 300 in the first direction D1 may be larger than the second length L2. The transparent substrate 300 may be formed of at least one of transparent glass, transparent resin, or transparent ceramic materials.

The mold layer 400 may be on the package substrate 1100 to hermetically seal the first image sensor chip C1, the second image sensor chip C2, the first to third bonding wires BW1, BW2, and BW3, and the transparent substrate 300. In detail, the mold layer 400 may be between the package substrate 1100 and the transparent substrate 300 to fill or be in a space between the first and second image sensor chips C1 and C2.

The mold layer 400 and the first and second dam structures 200a and 200b may prevent the first and second image sensor chips C1 and C2 from being contaminated by an external contamination material. In addition, the mold layer 400 may protect the semiconductor package 1000 from an external impact.

The mold layer 400 may have an inclined top surface, and a level of the top surface of the mold layer 400 may be lower than a level of the top surface of the transparent substrate 300. However, in some embodiments, the level of the top surface of the mold layer 400 may be substantially equal to the level of the top surface of the transparent substrate 300. The mold layer 400 may be formed of or include an insulating polymer (e.g., an epoxy molding compound).

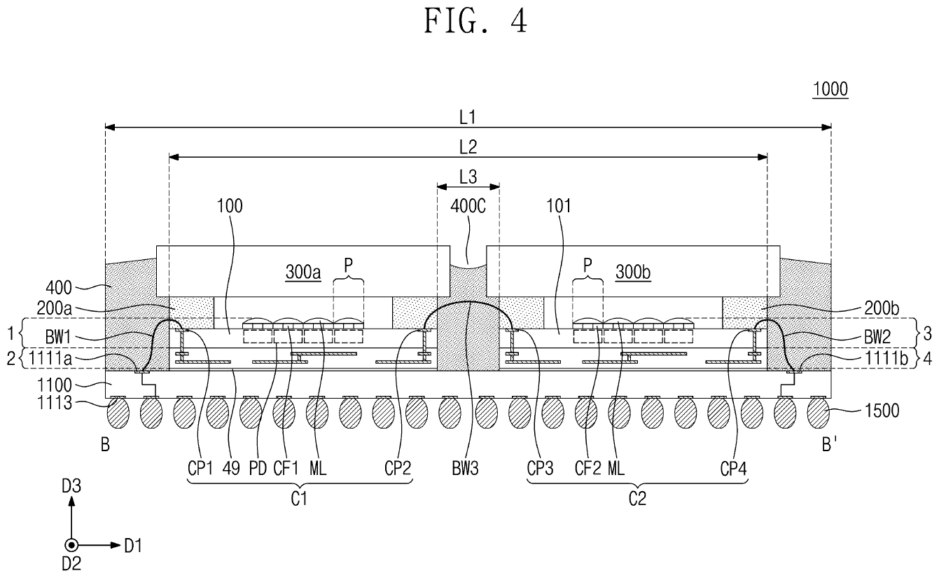

FIG. 3 is a plan view illustrating a semiconductor package according to some embodiments of the inventive concept. FIG. 4 is a sectional view taken along a line B-B′ of FIG. 3. An element previously described with reference to FIGS. 1 and 2 may be identified by the same reference number without repeating an overlapping description thereof.

Referring to FIGS. 3 and 4, the semiconductor package 1000 may include a first transparent substrate 300a and a second transparent substrate 300b. The first transparent substrate 300a may be vertically overlapped with the first image sensor chip C1. The second transparent substrate 300b may be vertically overlapped with the second image sensor chip C2. The first transparent substrate 300a may be in contact with the first dam structure 200a. The second transparent substrate 300b may be in contact with the second dam structure 200b.

The first and second transparent substrates 300a and 300b may be spaced apart from each other in the first direction D1. Here, a distance between the first and second dam structures 200a and 200b in the first direction D1 may be larger than a distance between the first and second transparent substrates 300a and 300b in the first direction D1.

In some embodiments, the first transparent substrate 300a may include an anti-reflective coating agent. The second transparent substrate 300b may include an infrared-blocking coating agent. Alternatively, the first transparent substrate 300a may include an infrared-blocking coating agent, and the second transparent substrate 300b may include an anti-reflective coating agent. In some embodiments, the types of the first and second transparent substrates 300a and 300b may be variously changed or combined. Since the first and second transparent substrates 300a and 300b include the coating agents of different types, it may be possible to diversify optical characteristics of light incident to the image sensor in the package.

The mold layer 400 may be provided on the package substrate 1100 to fill or be in a space between the first and second transparent substrates 300a and 300b. Here, the top surface of the mold layer 400, which is provided on the center region of the package substrate 1100, may have a concave portion 400C. The concave portion 400C may be exposed between the first and second transparent substrates 300a and 300b. That is, the concave portion 400C may be in a space between the first and second transparent substrates 300a and 300b and may not be covered by the first and second transparent substrates 300a and 300b.

FIG. 5 is a sectional view illustrating a semiconductor package according to some embodiments of the inventive concept. An element previously described with reference to FIGS. 1 to 4 may be identified by the same reference number without repeating an overlapping description thereof.

Referring to FIG. 5, the package substrate 1100 may include a first opening OP1 and a second opening OP2. The first opening OP1 may be vertically overlapped with the first image sensor chip C1 and the first transparent substrate 300a. The second opening OP2 may be vertically overlapped with the second image sensor chip C2 and the second transparent substrate 300b.

Connection terminals 1114 may be provided between the package substrate 1100 and the first image sensor chip C1 and between the package substrate 1100 and the second image sensor chip C2. The first and second image sensor chips C1 and C2 may be electrically connected to each other through the connection terminals 1114 and the internal interconnection lines of the package substrate 1100.

An adhesive member 401 may be provided on the package substrate 1100. In detail, the adhesive member 401 may be provided between the package substrate 1100 and the first image sensor chip C1, between the first and second image sensor chips C1 and C2, and between the package substrate 1100 and the second image sensor chip C2.

The outer connection terminals 1500 may be provided on the coupling pads 1113 on a bottom surface of the package substrate 1100.

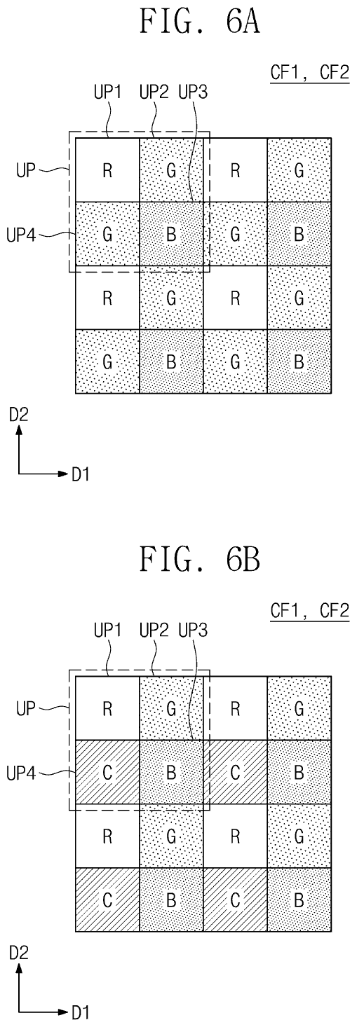

FIGS. 6A, 6B, 6C, and 6D are diagrams illustrating arrays of color filters according to some embodiments of the inventive concept. In detail, FIGS. 6A to 6D are diagrams illustrating possible examples of the array of the first and second color filters CF1 and CF2 of FIG. 2.

Here, the first array of the first color filters CF1 may be different from the second array of the second color filters CF2. In this case, optical characteristics (e.g., colors) of light passing through the color filters may be diversified in a semiconductor package. In some embodiments, the first array of the first color filters CF1 may be the same as the second array of the second color filters CF2.

Referring to FIGS. 2 and 6A, the color filters CF1 and CF2 may have an array, in which the unit patterns UP are two-dimensionally arranged. In some embodiments, the unit pattern UP may be arranged to have a 2×2 matrix structure.

The unit pattern UP may be composed of first to fourth unit filters UP1 to UP4. The first to fourth unit filters UP1 to UP4 may correspond to the unit pixels P described with reference to FIG. 2.

The first to fourth unit filters UP1 to UP4 may be arranged in a clockwise direction. As an example, the first unit filter UP1 and the second unit filter UP2 may be adjacent to each other in the first direction D1. The second unit filter UP2 and the third unit filter UP3 may be adjacent to each other in the second direction D2. The third unit filter UP3 and the fourth unit filter UP4 may be adjacent to each other in the first direction D1. The first unit filter UP1 and the fourth unit filter UP4 may be adjacent to each other in the second direction D2.

Each of the first to fourth unit filters UP1 to UP4 may allow light having a specific color to pass through. In some embodiments, the first unit filter UP1 may allow a red light R to pass through. The second and fourth unit filters UP2 and UP4 may allow green light G to pass through. The third unit filter UP3 may allow blue light B to pass through.

FIG. 6B is a diagram illustrating a color filter array according to some embodiments of the inventive concept. For concise description, an element previously described with reference to FIG. 6A may be identified by the same reference number without repeating an overlapping description thereof.

Referring to FIGS. 2 and 6B, the color filters CF1 and CF2 may have an array, in which the unit patterns UP are two-dimensionally arranged. The unit pattern UP may be composed of first to fourth unit filters UP1 to UP4. Each of the first to third unit filters UP1 to UP3 may allow light having a specific color to pass through. In some embodiments, the first unit filter UP1 may allow the red light R to pass through. The second unit filter UP2 may allow the green light G to pass through. The third unit filter UP3 may allow the blue light B to pass through. The fourth unit filter UP4 may be a transparent or clear filter C. The transparent filter C may allow light with all wavelength ranges to pass through.

FIG. 6C is a diagram illustrating a color filter array according to some embodiments of the inventive concept. For concise description, an element previously described with reference to FIG. 6A may be identified by the same reference number without repeating an overlapping description thereof.

Referring to FIGS. 2 and 6C, the color filters CF1 and CF2 may have an array, in which the unit patterns UP are two-dimensionally arranged. The unit pattern UP may be composed of first to fourth unit filters UP1 to UP4. Each of the first and third unit filters UP1 and UP3 may allow light having a specific color to pass through. In some embodiments, the first unit filter UP1 may allow the red light R to pass through. The third unit filter UP3 may allow the blue light B to pass through. The second and fourth unit filters UP2 and UP4 may be transparent or clear filters C. The transparent filter C may allow light with all wavelength ranges to pass through.

FIG. 6D is a diagram illustrating a color filter array according to some embodiments of the inventive concept. For concise description, an element previously described with reference to FIG. 6A may be identified by the same reference number without repeating an overlapping description thereof.

Referring to FIGS. 2 and 6D, the color filters CF1 and CF2 may have an array, in which the unit patterns UP are two-dimensionally arranged. The unit pattern UP may be composed of the first to fourth unit filters UP1 to UP4. Each of the first to fourth unit filters UP1 to UP4 may allow light having a specific color to pass through. In some embodiments, the first unit filter UP1 may allow the red light R to pass through. The second and fourth unit filters UP2 and UP4 may allow yellow light Y to pass through. The third unit filter UP3 may allow cyan light Cy to pass through.

FIG. 7 is a sectional view illustrating an image sensor according to some embodiments of the inventive concept. In detail, FIG. 7 is a diagram illustrating the first sensor and logic units 1 and 2 of the first image sensor chip C1 described with reference to FIG. 2.

Although not shown, the second sensor unit 3 and the second logic unit 4 of the second image sensor chip C2 may have substantially the same or similar structure as the first sensor and logic units 1 and 2 of the first image sensor chip C1. For concise description, an element previously described with reference to FIG. 2 may be identified by the same reference number without repeating an overlapping description thereof.

Referring to FIG. 7, the first image sensor chip C1 may include a pixel array region R1 and a pad region R2. The pixel array region R1 may include a light-receiving region AR and a light-blocking region OB. The light-blocking region OB may be provided between the light-receiving region AR and the pad region R2.

The first image sensor chip C1 may include the first sensor and logic units 1 and 2. The first sensor unit 1 may include a photoelectric conversion layer 10, a readout circuit layer 20, and an optically-transparent layer 30. When viewed in a vertical section, the photoelectric conversion layer 10 may be between the readout circuit layer 20 and the optically-transparent layer 30.

The photoelectric conversion layer 10 of the first sensor unit 1 may include the first semiconductor substrate 100, an isolation structure PIS, and the photoelectric conversion parts PD. The first semiconductor substrate 100 may include a first surface 100a and a second surface 100b, which are opposite to each other. Light may be incident into the first semiconductor substrate 100 through the second surface 100b.

A device isolation layer STI may be adjacent to the first surface 100a of the first semiconductor substrate 100. The device isolation layer STI may define an active region in the first surface 100a of the first semiconductor substrate 100. The device isolation layer STI may include an insulating material.

The isolation structures PIS may be provided in the first semiconductor substrate 100 to separate the photoelectric conversion parts PD from each other. The isolation structure PIS may be extended from the first surface 100a of the first semiconductor substrate 100 to the second surface 100b. The isolation structure PIS may be provided to partially penetrate the device isolation layer STI. The isolation structure PIS may be provided to enclose each of the photoelectric conversion parts PD, when viewed in a plan view.

The isolation structure PIS may include a liner insulating pattern 103, a semiconductor pattern 105, and a gapfill insulating pattern 107. The semiconductor pattern 105 may be formed of or include doped polysilicon or a metallic material.

The liner insulating pattern 103 may be provided between the semiconductor pattern 105 and the first semiconductor substrate 100. The gapfill insulating pattern 107 may be below the semiconductor pattern 105. The liner insulating pattern 103 and the gapfill insulating pattern 107 may be formed of or include silicon oxide.

In the light-blocking region OB, the semiconductor pattern 105 may be connected to a bias contact plug PLG. The bias contact plug PLG may include at least one of metallic materials and/or metal nitride materials. For example, the bias contact plug PLG may be formed of or include at least one of titanium and/or titanium nitride.

A contact pattern CT may be buried in a contact hole provided with the bias contact plug PLG. The contact pattern CT may include a material different from the bias contact plug PLG. For example, the contact pattern CT may be formed of or include aluminum (Al).

A negative bias may be applied to the semiconductor pattern 105 through the contact pattern CT and the bias contact plug PLG. The negative bias may be transmitted from the light-blocking region OB to the light-receiving region AR. Since a negative bias is applied to the semiconductor pattern 105 of the isolation structure PIS, a dark current, which is produced at a boundary between the isolation structure PIS and the first semiconductor substrate 100, may be reduced.

Transfer gate electrodes TG may be on the first surface 100a of the first semiconductor substrate 100. A portion of the transfer gate electrode TG may be extended into the first semiconductor substrate 100, and a gate insulating layer may be interposed between the transfer gate electrode TG and the first semiconductor substrate 100. The gate insulating layer may be formed of or include at least one of silicon oxide, silicon oxynitride, high-k dielectric materials having dielectric constants higher than silicon oxide, or combinations thereof.

A floating diffusion region may be provided in a portion of the first semiconductor substrate 100, which is provided at a side of the transfer gate electrode TG. The floating diffusion region may be formed by injecting impurities that are different from those in the first semiconductor substrate 100. For example, the floating diffusion region may be an n-type impurity region.

The readout circuit layer 20 may be on the first surface 100a of the first semiconductor substrate 100. The readout circuit layer 20 may include readout circuits (e.g., MOS transistors), which are connected to the photoelectric conversion layer 10. The readout circuit layer 20 may be configured to process electrical signals, which are converted by the photoelectric conversion layer 10. The readout circuit layer 20 may include pixel transistors (e.g., a reset transistor, a source follower transistor, and a selection transistor).

In detail, the readout circuit layer 20 may include MOS transistors, which are on a bottom surface of the first semiconductor substrate 100, connection lines CL, which are connected to the MOS transistors, and interlayer insulating layers ILD, which are interposed between the connection lines CL. The connection lines CL may be provided in a multi-layered structure, the connection lines CL, which are placed at different levels, may be connected to each other through contact plugs. The interlayer insulating layers ILD may be provided on the first surface 100a of the first semiconductor substrate 100 to cover the transfer gate electrode TG and the pixel transistors.

The optically-transparent layer 30 may be on the second surface 100b of the first semiconductor substrate 100. The optically-transparent layer 30 may include a lower planarization insulating layer 310, a grid 320, a protection layer 330, a first color filter CF1, a light-blocking pattern OBP, the micro lenses ML, and a passivation layer PL. The optically-transparent layer 30 may be provided to condense and filter light, which is incident from the outside, and to provide the light to the photoelectric conversion layer 10.

The lower planarization insulating layer 310 may cover the second surface 100b of the first semiconductor substrate 100. The lower planarization insulating layer 310 may be extended from the light-receiving region AR to the light-blocking region OB and the pad region R2.

The lower planarization insulating layer 310 may be formed of a transparent insulating material and may include a plurality of layers. The lower planarization insulating layer 310 may be formed of an insulating material having a refractive index different from the first semiconductor substrate 100. The lower planarization insulating layer 310 may include metal oxide and/or silicon oxide. The lower planarization insulating layer 310 may be provided to have a single-or multi-layered structure. As an example, the lower planarization insulating layer 310 may be formed of metal oxide or metal fluoride containing at least one metallic element that is selected from the group consisting of hafnium (Hf), zirconium (Zr), aluminum (Al), tantalum (Ta), titanium (Ti), yttrium (Y), and lanthanum (La). For example, the lower planarization insulating layer 310 may include an aluminum oxide layer and/or a hafnium oxide layer.

The grid 320 may be on the lower planarization insulating layer 310. The grid 320 may include a light-blocking pattern and/or a low refractive pattern. The light-blocking pattern may be formed of or include at least one of metallic materials (e.g., titanium, tantalum, or tungsten). The low refractive pattern may be formed of a material having a refractive index lower than the light-blocking pattern. The low refractive pattern may be formed of an organic material and may have a refractive index of about 1.1 to 1.3.

The protection layer 330 may cover the lower planarization insulating layer 310 and the grid 320. The protection layer 330 may be formed of or include at least one of aluminum oxide or silicon oxide. The protection layer 330 may be extended from the light-receiving region AR to the light-blocking region OB and the pad region R2.

The first color filters CF1 may be correspond to the photoelectric conversion parts PD, respectively. The first color filters CF1 may fill or be in a space defined by the grid 320.

The micro lenses ML may be on the first color filters CF1. The micro lenses ML may have a convex shape and may have a specific curvature radius.

In the light-blocking region OB, the light-blocking pattern OBP may be on the lower planarization insulating layer 310 and the protection layer 330. The light-blocking pattern OBP may be provided to prevent light from entering the photoelectric conversion parts PD in the light-blocking region OB. The light-blocking pattern OBP may be formed of or include at least one of metallic materials (e.g., tungsten, copper, aluminum, or alloys thereof).

In the light-blocking region OB, a first penetration conductive pattern 511 may be provided to penetrate the first semiconductor substrate 100 and to electrically connect the connection lines CL of the readout circuit layer 20 to an interconnection structure 1117 of the logic unit 2. A first penetration conductive pattern 531 may have a first bottom surface and a second bottom surface, which are located at different levels. A first gapfill pattern 521 may be provided in the first penetration conductive pattern 531. The first gapfill pattern 521 may include a low refractive material and may have an insulating property.

A bulk filtering layer CFB may be provided on the light-blocking pattern OBP. The bulk filtering layer CFB may be configured to block light having a wavelength different from the first color filters CF1. For example, the bulk filtering layer CFB may be configured to block the infrared light. The bulk filtering layer CFB may include a blue color filter, but the inventive concept is not limited to this example.

An upper planarization layer TPL may be provided in the pixel array region R1 to cover the first color filter CF1 and the bulk filtering layer CFB. The upper planarization layer TPL may be configured to expose the top surfaces of conductive pads CP in the pad region R2.

In the pad region R2, the first conductive pad CP1 may be provided on the second surface 100b of the first semiconductor substrate 100. The first conductive pad CP1 may be buried in the second surface 100b of the first semiconductor substrate 100. In some embodiments, the first conductive pad CP1 may be provided in a pad trench, which is formed in the second surface 100b of the first semiconductor substrate 100 and in the pad region R2. Referring to FIG. 2, although not shown, the second conductive pad CP2 may also be provided on the second surface 100b of the first semiconductor substrate 100.

In the pad region R2, a second penetration conductive pattern 533 may be provided penetrate the first semiconductor substrate 100 and may be electrically connected to the interconnection structure 1117 of the first logic unit 2. The second penetration conductive pattern 533 may be extended to a region on the second surface 100b of the first semiconductor substrate 100 and may be electrically connected to the conductive pads CP. A portion of the second penetration conductive pattern 533 may be provided to cover the bottom and side surfaces of the conductive pads CP. A second gapfill pattern 543 may be provided in the second penetration conductive pattern 533. The second gapfill pattern 543 may include a low refractive material and may have an insulating property. The isolation structures PIS may be provided in the pad region R2 and around the second penetration conductive pattern 533.

The first logic unit 2 may be adjacent to the readout circuit layer 20 of the first sensor unit 1. The first logic unit 2 may include a power circuit, an input/output interface, and an image signal processor. The first logic unit 2 may include a logic semiconductor substrate 1007, logic circuits, interconnection structures 1117 connected to the logic circuits, and logic interlayer insulating layers 1107. The uppermost one of the logic interlayer insulating layers 1107 may be in contact with the readout circuit layer 20 of the first sensor unit 1. The first logic unit 2 may be electrically connected to the first sensor unit 1 through the first and second penetration conductive patterns 531 and 533.

FIG. 7 illustrates an example, in which the first sensor and logic units 1 and 2 are electrically connected to each other through the first and second penetration conductive patterns 531 and 533, but the inventive concept is not limited to this example. In some embodiments, the first and second penetration conductive patterns of FIG. 7 may be omitted, and in this case, the first sensor and logic units 1 and 2 may be electrically connected to each other by bonding their bonding pads to each other.

According to some embodiments of the inventive concept, a semiconductor package may include a first image sensor chip and a second image sensor chip, which are on a package substrate, and bonding wires, which are provided to connect them to each other. Here, the first and second image sensor chips may be of different kinds from each other. In some embodiments, the first image sensor chip may be different from the second image sensor chip in terms of resolution, the kind of the color filter array, the kind of the transparent substrate, and the operation circuit of the logic unit. In the case where two image sensor chips use different color filter arrays and different transparent substrates, the sensitivity controlling ability of the color may be improved, and a single fused image may be obtained from two images.

That is, a plurality of image sensor chips having different characteristics may be mounted on a single package substrate, and thus, the semiconductor package may have various characteristics. In addition, since the image sensor chips on a single package substrate are connected to each other using the bonding wire, a speed of processing electrical signals between the image sensor chips in the semiconductor package may be increased.

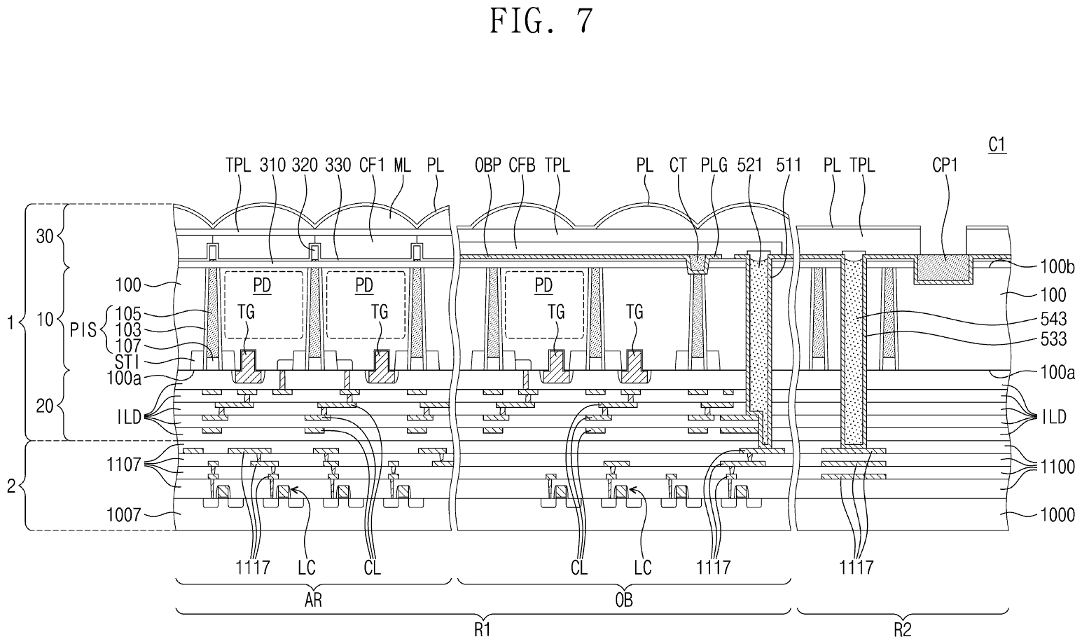

FIGS. 8, 9, and 10 are sectional views illustrating a process of fabricating an image sensor according to some embodiments of the inventive concept. In detail, FIGS. 8 to 10 are sectional views illustrating a process of fabricating the semiconductor package 1000 of FIG. 2.

Referring to FIG. 8, the package substrate 1100 may be provided. The package substrate 1100 may include the bonding pads 1111a and 1111b on a top surface thereof, the coupling pads 1113 on a bottom surface thereof, and internal interconnection lines.

The first and second image sensor chips C1 and C2 may be mounted on the package substrate 1100 through the bonding tape 49.

The first image sensor chip C1 may include the first sensor unit 1 and the first logic unit 2. The first sensor unit 1 may include the first semiconductor substrate 100, the first color filter CF1, and the micro lens ML.

The first semiconductor substrate 100 may include the photoelectric conversion parts PD, the first conductive pad CP1, and the second conductive pad CP2. The photoelectric conversion parts PD in the first semiconductor substrate 100 may be formed in the first semiconductor substrate 100 through an ion implantation process. The first image sensor chip C1 may further include the readout circuit layer 20, as described with reference to FIG. 7.

The second image sensor chip C2 may include the second sensor unit 3 and the second logic unit 4. The second sensor unit 3 may include the second semiconductor substrate 101, the second color filter CF2, and the micro lens ML. The second semiconductor substrate 101 may include the photoelectric conversion parts PD, the third conductive pad CP3, and the fourth conductive pad CP4. The photoelectric conversion parts PD in the second semiconductor substrate 101 may be formed in the second semiconductor substrate 101 through an ion implantation process. The second image sensor chip C2 may further include the readout circuit layer 20, as described with reference to FIG. 6.

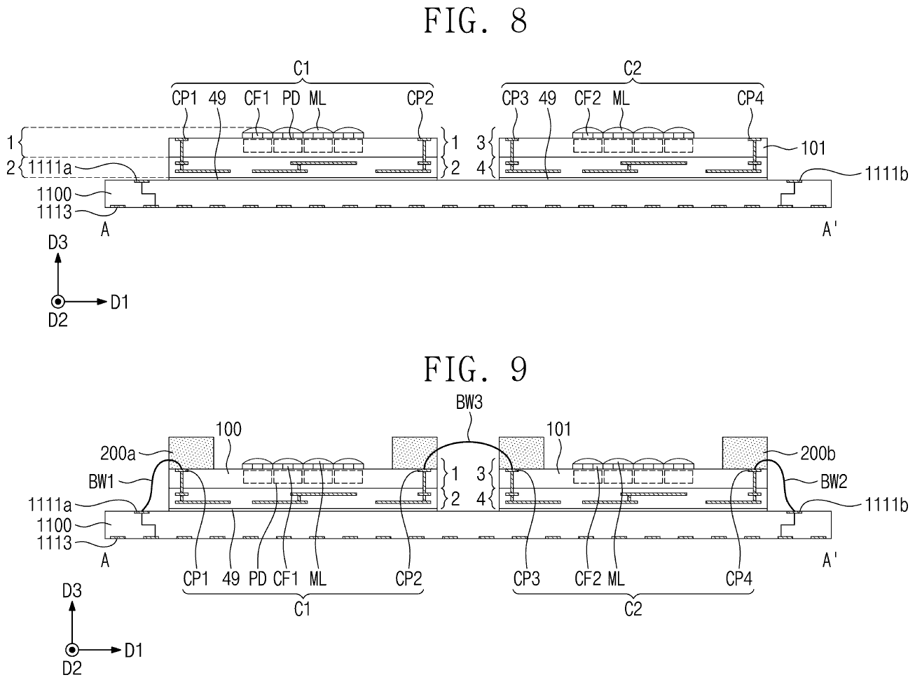

Referring to FIG. 9, the first bonding wire BW1 may be formed to connect the first conductive pad CP1 to the first bonding pad 1111a. The second bonding wire BW2 may be formed to connect the fourth conductive pad CP4 to the second bonding pad 1111b. The third bonding wire BW3 may be formed to connect the second conductive pad CP2 to the third conductive pad CP3. In some embodiments, the first bonding wire BW1, the second bonding wire BW2, and the third bonding wire BW3 may be formed using a capillary.

The first dam structure 200a may be formed on the edge portion of the first image sensor chip C1. The first dam structure 200a may cover the first conductive pad CP1 and the second conductive pad CP2. The second dam structure 200b may be formed on an edge of the second image sensor chip C2. The second dam structure 200b may cover the third and fourth conductive pads CP3 and CP4.

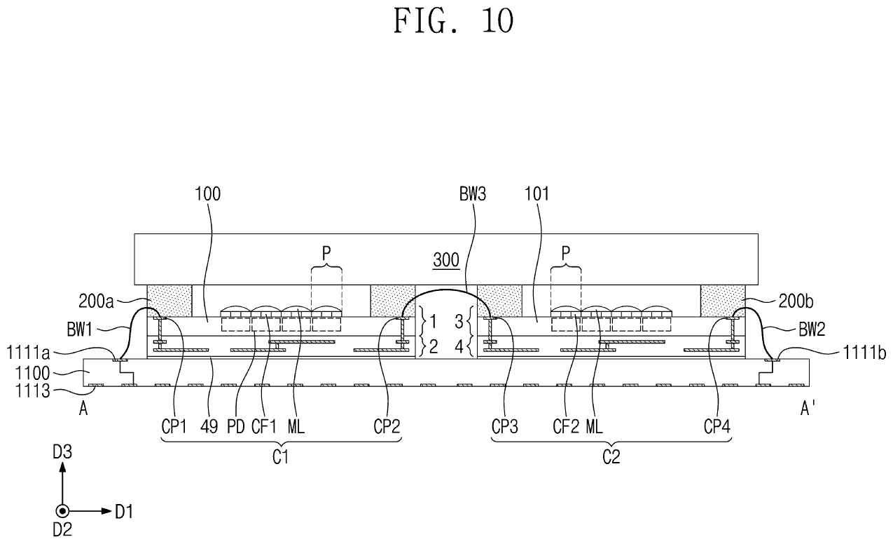

Referring to FIG. 10, the transparent substrate 300 may be on the first and second image sensor chips C1 and C2. The transparent substrate 300 may be in contact with the first and second dam structures 200a and 200b.

Next, referring back to FIG. 2, the semiconductor package may be formed by forming the mold layer 400 on the package substrate 1100 and attaching the outer connection terminals 1500 to the coupling pads 1113.

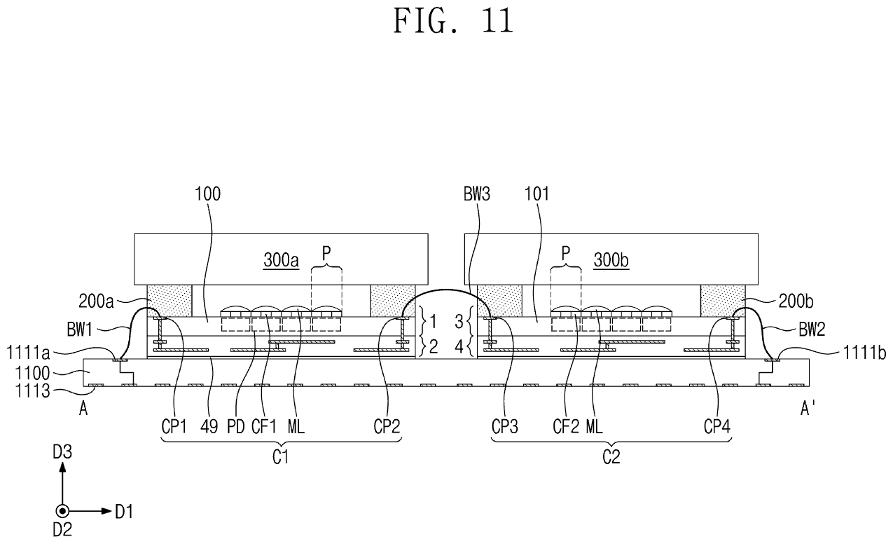

FIG. 11 is a sectional view illustrating a portion of a process of fabricating an image sensor according to some embodiments of the inventive concept. In detail, FIG. 11 is a sectional view illustrating a process of fabricating the semiconductor package 1000 of FIG. 4.

Referring to FIGS. 8, 9, and 11, the first transparent substrate 300a may be on the first dam structure 200a. The second transparent substrate 300b may be on the second dam structure 200b. The first and second transparent substrates 300a and 300b may be spaced apart from each other in the first direction D1.

Next, referring back to FIG. 4, the semiconductor package may be formed by forming the mold layer 400 on the package substrate 1100 and attaching the outer connection terminals 1500 to the coupling pads 1113.

According to some embodiments of the inventive concept, a semiconductor package may include a first image sensor chip and a second image sensor chip, which are on a package substrate, and a bonding wire, which is provided to connect them to each other. Here, the first and second image sensor chips may be of different kinds from each other. As a result, a plurality of image sensor chips having different characteristics may be mounted on a single package substrate, and thus, the semiconductor package may have various characteristics.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a package substrate;
a first image sensor chip and a second image sensor chip on the package substrate and spaced apart from each other in a first direction; and
a bonding wire connecting the first image sensor chip to the second image sensor chip,
wherein the first image sensor chip comprises a first conductive pad,
the second image sensor chip comprises a second conductive pad, and
the bonding wire is connected to the first and second conductive pads.

2. The semiconductor package of claim 1, further comprising:
a transparent substrate on the first and second image sensor chips;
a first dam structure on an edge portion of the first image sensor chip and between the first image sensor chip and the transparent substrate; and
a second dam structure on an edge portion of the second image sensor chip and between the second image sensor chip and the transparent substrate.

3. The semiconductor package of claim 2, further comprising a mold layer between the package substrate and the transparent substrate,
wherein the mold layer is on the package substrate and in a space between the first and second image sensor chips.

4. The semiconductor package of claim 3, wherein the transparent substrate comprises:
a first transparent substrate contacting the first dam structure; and
a second transparent substrate contacting the second dam structure,
wherein the first and second transparent substrates are spaced apart from each other in the first direction.

5. The semiconductor package of claim 4, wherein the mold layer is in a space between the first and second transparent substrates.

6. The semiconductor package of claim 4, wherein a top surface of the mold layer in a center region of the package substrate comprises a concave portion, and
the concave portion is exposed between the first and second transparent substrates.

7. The semiconductor package of claim 4, wherein a distance between the first and second dam structures in the first direction is larger than a distance between the first and second transparent substrates in the first direction.

8. The semiconductor package of claim 4, wherein the first transparent substrate comprises an anti-reflective coating agent, and
the second transparent substrate comprises an infrared-blocking coating agent.

9. A semiconductor package, comprising:
a package substrate; and
a first image sensor chip and a second image sensor chip on the package substrate and spaced apart from each other in a first direction,
wherein the package substrate has a first length in the first direction parallel to a top surface of the package substrate,
the first image sensor chip has a first side surface and a second side surface, which are opposite to each other in the first direction,
the second image sensor chip has a third side surface and a fourth side surface, which are opposite to each other in the first direction,
the first side surface is closer to an edge of the package substrate than the second side surface,
the fourth side surface is closer to an edge of the package substrate than the third side surface,
a distance between the first and fourth side surfaces in the first direction has a second length, and
the second length is 70 % to 80 % of the first length.

10. The semiconductor package of claim 9, wherein a distance between the second and third side surfaces in the first direction is about 60 μm.

11. The semiconductor package of claim 9, wherein the package substrate comprises a first opening and a second opening,
the first opening vertically overlaps the first image sensor chip,
the second opening vertically overlaps the second image sensor chip, and
the semiconductor package further comprises a connection terminal between the package substrate and the first image sensor chip and between the package substrate and the second image sensor chip.

12. The semiconductor package of claim 9, further comprising a first bonding wire connecting the first image sensor chip to the second image sensor chip,
wherein the first image sensor chip comprises a first semiconductor substrate and first and second conductive pads on the first semiconductor substrate and adjacent to the first and second side surfaces, respectively, and
the second image sensor chip comprises a second semiconductor substrate and third and fourth conductive pads on the second semiconductor substrate and adjacent to the third and fourth side surfaces, respectively.

13. The semiconductor package of claim 12, wherein the first bonding wire is connected to the second conductive pad and the third conductive pad.

14. The semiconductor package of claim 12, wherein the package substrate comprises a first bonding pad and a second bonding pad spaced apart from each other in the first direction,
the semiconductor package further comprises:
a second bonding wire connecting the first bonding pad to the first conductive pad; and
a third bonding wire connecting the second bonding pad to the fourth conductive pad.

15. A semiconductor package, comprising:
a package substrate;
a first image sensor chip and a second image sensor chip on the package substrate and spaced apart from each other in a first direction parallel to a top surface of the package substrate;
a first bonding wire connecting the package substrate to the first image sensor chip;
a second bonding wire connecting the package substrate to the second image sensor chip;
a third bonding wire connecting the first image sensor chip to the second image sensor chip;
a transparent substrate on the first and second image sensor chips; and
a mold layer between the package substrate and the transparent substrate.

16. The semiconductor package of claim 15, wherein the mold layer is on the package substrate and in a space between the first and second image sensor chips, and
a center portion of the transparent substrate is in contact with the mold layer.

17. The semiconductor package of claim 15, wherein the first image sensor chip comprises a first semiconductor substrate,
the second image sensor chip comprises a second semiconductor substrate, and
each of the first and second semiconductor substrates comprises a plurality of photoelectric conversion parts.

18. The semiconductor package of claim 17, wherein a number of the photoelectric conversion parts per unit area included in the first semiconductor substrate is different from a number of the photoelectric conversion parts per unit area included in the second semiconductor substrate.

19. The semiconductor package of claim 17, wherein the first image sensor chip comprises first color filters on the first semiconductor substrate,
the second image sensor chip further comprises second color filters on the second semiconductor substrate, and
a first array of the first color filters is different from a second array of the second color filters.

20. The semiconductor package of claim 19, further comprising a micro lens on the first color filters and the second color filters.
